(19) United States
(12) Patent Application Publication
(10) Pub. No.: US 2025/0210537 A1
(43) Pub. Date: Jun. 26, 2025

(54) SEMICONDUCTOR DEVICE

(71) Applicant: Novatek Microelectronics Corp., Hsinchu (TW)

(72) Inventors: Chiang-Chi Peng, Hsinchu City (TW); Yi-Chia Chen, Taichung City (TW); Ting-Yu Hu, Hsinchu County (TW); Chien-Chen Ko, Hsinchu City (TW)

(73) Assignee: Novatek Microelectronics Corp., Hsinchu (TW)

(21) Appl. No.: 18/391,664

(22) Filed: Dec. 21, 2023

(51) Int. Cl. H01L 23/544; H01L 23/48

(52) U.S. Cl. CPC H01L 23/544; H01L 23/481; H01L 2223/54426

(57) ABSTRACT

A semiconductor device includes a substrate, an upper layer disposed over the substrate and comprises an upper electrical pattern and an alignment mark pattern electrically insulated from the upper electrical pattern, and a lower layer disposed between the substrate and the upper layer and including a lower electrical pattern and a dummy pattern electrically insulated from the lower electrical pattern, wherein the alignment mark pattern overlaps the dummy pattern from a top view, the alignment mark pattern has an optical contrast in relation to the dummy pattern, and the optical contrast is substantially equal to or greater than 50.

### BACKGROUND

### Technical Field

The present disclosure generally relates to a semiconductor device. More particularly, the present disclosure relates to a semiconductor device having an alignment mark pattern.

### Description of Related Art

Semiconductor devices formed on a semiconductor substrate are typically assembled for connection to external devices and also packaged to protect these semiconductor devices from the external environment. In particular, a semiconductor device may have a pad electrode layer used as an input/output terminal for being connected to an external device, and an alignment mark used as an alignment key for assembling the semiconductor device.

Specifically, an alignment mark pattern is formed over a semiconductor substrate. Generally, the alignment mark pattern is formed in an alignment region of the device which is formed of an insulating layer for isolation. An optical alignment apparatus perceives the contrast between the alignment region (i.e., surrounding of the alignment mark pattern) and a portion of the alignment mark pattern and aligns a semiconductor device by using this contrast between the alignment region and the alignment mark pattern. However, if there is any other circuit layer underneath the alignment mark pattern extending into a region right under the alignment mark pattern, the contract between the alignment region and the alignment mark pattern may be reduced, which may result in an alignment error for these semiconductor devices. Therefore, there is a circuit clearance region, which is not allowed for circuit routing, extending from the alignment region all the way to the substrate, which is a significant waste of space in semiconductor devices.

### SUMMARY

Accordingly, the present disclosure is directed to a touch display device with photo sensors, which is capable of collimating lights to the optical sensor to improve sensing output. The present disclosure provides a semiconductor device including a substrate, an upper layer disposed over the substrate and comprises an upper electrical pattern and an alignment mark pattern electrically insulated from the upper electrical pattern, and a lower layer disposed between the substrate and the upper layer and including a lower electrical pattern and a dummy pattern electrically insulated from the lower electrical pattern, wherein the alignment mark pattern overlaps the dummy pattern from a top view, the alignment mark pattern has an optical contrast in relation to the dummy pattern, and the optical contrast is substantially equal to or greater than 50.

According to an embodiment of the present disclosure, wherein the upper layer comprises a clearance area surrounding the alignment mark pattern, and the upper electrical pattern is disposed outside the clearance area.

According to an embodiment of the present disclosure, the dummy pattern completely filling the clearance area from a top view.

According to an embodiment of the present disclosure, the upper electrical pattern is spaced apart from the clearance area by a gap, which is substantially equal to or greater than 5 μm.

According to an embodiment of the present disclosure, the semiconductor device further includes an interconnect structure disposed between the lower layer and the substrate, and a part of the interconnect circuit of the interconnect structure overlaps the dummy pattern from a top view.

According to an embodiment of the present disclosure, the interconnect structure is electrically connected to the lower electrical pattern and electrically insulated from the dummy pattern.

According to an embodiment of the present disclosure, the upper electrical pattern comprises a bonding pad for bonding with an electrical connector and material of the upper layer comprises aluminium, or aluminium titanium nitride.

According to an embodiment of the present disclosure, the material of the lower layer comprises copper.

According to an embodiment of the present disclosure, the upper electrical pattern comprises an electrical connector, and material of the upper layer comprises gold, or a multilayer of Cu/Ni/Au.

According to an embodiment of the present disclosure, the material of the lower layer comprises aluminium.

According to an embodiment of the present disclosure, the alignment mark pattern is electrically insulated from the dummy pattern.

According to an embodiment of the present disclosure, the optical contrast is a difference between a grey scale value of the dummy pattern and a grey scale value of the alignment mark pattern.

According to an embodiment of the present disclosure, a ratio of a grey scale value of the dummy pattern to a grey scale value of the alignment mark pattern is substantially equal to or greater than 1.3.

The present disclosure provides a semiconductor device including a substrate, an upper layer disposed over the substrate and including an upper electrical pattern and an alignment mark pattern electrically insulated from the upper electrical pattern, a lower layer disposed between the substrate and the upper layer and comprising a lower electrical pattern and a dummy pad electrically insulated from the lower electrical pattern, wherein the alignment mark pattern overlaps the dummy pad from a top view; and an interconnect structure disposed between the lower layer and the substrate, wherein a part of the interconnect circuit of the interconnect structure overlaps the dummy pattern from a top view.

According to an embodiment of the present disclosure, the alignment mark pattern has an optical contrast in relation to the dummy pad, and the optical contrast is substantially equal to or greater than 50.

According to an embodiment of the present disclosure, the part of the interconnect circuit pattern overlaps the clearance area from a top view.

In light of the foregoing, the semiconductor device of the disclosure is configured with a dummy pattern of a lower layer underneath the alignment mark pattern of the upper layer. As such, the material of the dummy pattern and the material of the alignment mark pattern are selected in pair such that the alignment mark pattern has an optical contrast in relation to the dummy pattern, and the optical contrast is substantially equal to or greater than 50 and therefore the alignment mark pattern 124 could be well recognized by a camera. Owing to the configuration of the dummy pattern interposed between the alignment mark pattern and the interconnect structure, a part of the interconnect circuit of the interconnect structure could overlap the dummy pattern from a top view since the dummy pattern blocks the interconnect circuit underneath and provides sufficient optical contrast for the camera to recognize the alignment mark. Thereby, space usage efficiency of the semiconductor device and flexibility in designing circuit routing are significantly increased.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of a semiconductor device according to some exemplary embodiments in the present disclosure.

FIG. 2 is a schematic top view of an upper layer of a semiconductor device according to some exemplary embodiments in the present disclosure.

FIG. 3 is a schematic top view of a lower layer of a semiconductor device according to some exemplary embodiments in the present disclosure.

FIG. 4 is a schematic top view of an interconnect structure of a semiconductor device according to some exemplary embodiments in the present disclosure.

FIG. 5 is a schematic top view of an upper layer and a lower layer of a semiconductor device according to some exemplary embodiments in the present disclosure.

FIG. 6 is a schematic top view of a semiconductor device according to some exemplary embodiments in the present disclosure.

FIG. 7 is a schematic cross-sectional view of a semiconductor device according to another exemplary embodiment in the present disclosure.

FIG. 8 is a schematic top view of a semiconductor device according to another exemplary embodiments in the present disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Reference will now be made in detail to the present preferred embodiments of the disclosure, examples of which are illustrated in the accompanying drawings. Wherever possible, the same reference numbers are used in the drawings and the description to refer to the same or like parts. The terms used herein such as “on”, “above”, “below”, “front”, “back”, “left” and “right” are for the purpose of describing directions in the figures only and are not intended to be limiting of the disclosure. Further, in the discussion and claims herein, the term “on” used with respect to two materials, one “on” the other, means at least some contact between the materials, while “over” and “overlie” mean the materials are in proximity, but possibly with one or more additional intervening materials such that physical contact is possible but not required. Neither “on” nor “over” implies any directionality as used herein.

Unless limited otherwise, the terms “disposed”, “connected”, “coupled”, “mounted” and variations thereof herein are used broadly and encompass direct and indirect connections, couplings, and mountings. Similarly, the terms “facing”, “faces” and variations thereof herein are used broadly and encompass direct and indirect facing, and “adjacent to” and variations thereof herein are used broadly and encompass directly and indirectly “adjacent to”. Accordingly, the drawings and descriptions will be regarded as illustrative in nature and not as restrictive.

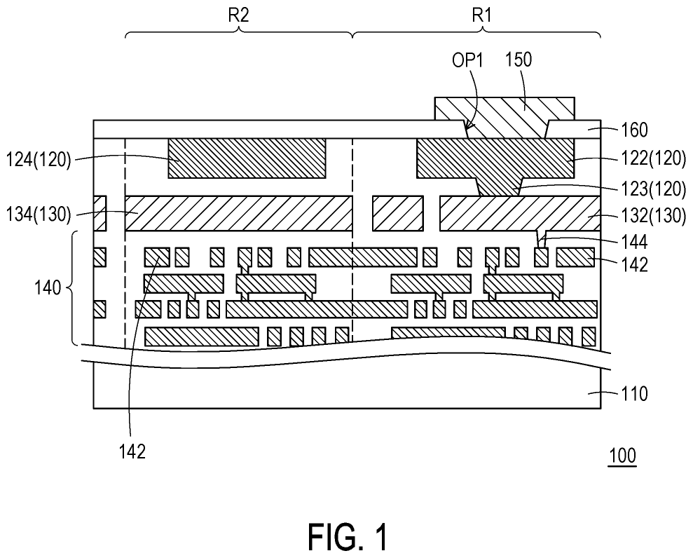

FIG. 1 is a schematic cross-sectional view of a semiconductor device according to some exemplary embodiments in the present disclosure. Referring to FIG. 1, in some embodiments, the semiconductor device 100 includes a substrate 110, an upper layer 120 disposed over the substrate 110, and a lower layer 130 disposed between the substrate 110 and the upper layer 120. The substrate 110 may be a semiconductor substrate, such as a bulk semiconductor, a semiconductor-on-insulator (SOI) substrate, or the like, which may be doped (e.g., with a p-type or an n-type dopant) or undoped. The substrate 110 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In some embodiments, a device layer (not shown) may be formed over the substrate 110. In some embodiments, the device layer may include an elementary semiconductor including silicon and/or germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GalnP, and/or GaInAsP; or combinations thereof. The device layer may include various doped regions depending on design requirements (e.g., p-type wells or n-type wells). The doped regions include various active regions, such as regions configured for an N-type metal-oxide-semiconductor transistor (referred to as an NMOS) and regions configured for a P-type metal-oxide-semiconductor transistor (referred to as a PMOS). However, the disclosure is not limited thereto.

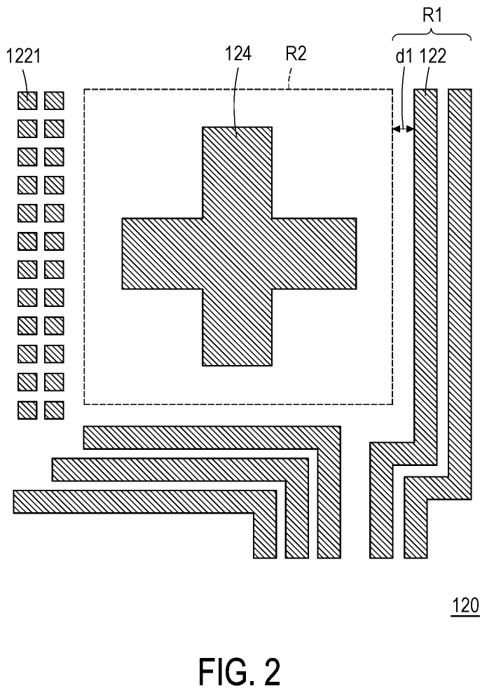

FIG. 2 is a schematic top view of an upper layer of a semiconductor device according to some exemplary embodiments in the present disclosure. Referring to FIG. 1 and FIG. 2, in some embodiments, the upper layer 120 is disposed over the substrate 110 and includes an upper electrical pattern 122 and an alignment mark pattern 124 electrically insulated from the upper electrical pattern 122. In the present embodiment, the upper layer 120 is a metallization layer, and the upper electrical pattern 122 includes a plurality of bonding pads for bonding with an electrical connector 150. That is, the alignment mark pattern 124 is formed with the upper electrical pattern 122 in the same layer (level) simultaneously by one pattering process, such as photolithography process, or the like. As such, material of the upper layer 120 may include aluminium (Al), or aluminium with titanium nitride (TiN), which is an aluminium patterned layer covered with an intermediate conductive layer such as metal alloy of titanium nitride. In other embodiment, the material of the alignment mark pattern 124 may include silicon (Si), or the like.

In detail, the upper layer 120 includes an integrated circuit region R1 (e.g., the integrated circuit region R1 shown in FIG. 1 and FIG. 2) in which an integrated circuit (including the upper electrical pattern 122, etc.) is formed, and an alignment mark region R2 in which the alignment mark pattern 124 is formed for aligning and positioning, for example, during mounting the semiconductor device 100 on a mounting substrate, or the like. In the present embodiment, a plurality of metallization layers (including the upper electrical pattern 122, the lower electrical pattern 132, the interconnect structure 142, etc.) are formed across a plurality of layers and the alignment mark pattern 124 is formed in the same layer of the uppermost metallization layer among the metallization layers. In some embodiments, the upper layer 120 may further include a plurality of dummy grids 1221, which are electrically insulated from the upper electrical pattern 122 and the alignment mark pattern 124, for reducing issue of stress concentration.

Referring to FIG. 2, in some embodiments, the upper layer 120 includes a clearance area, which is a portion in the alignment mark region R2 that surrounds the alignment mark pattern 124, and the upper electrical pattern 122 is disposed outside the clearance area, so as to ensure contrast difference between the alignment mark pattern 124 and the background without interference of the upper electrical pattern 122. In one embodiment, the upper electrical pattern 122 is spaced apart from the clearance area of the alignment mark region R2 by a gap d1. In the present embodiment, the gap d1 may be substantially equal to or greater than 5 μm. In the present embodiment, the alignment mark pattern 124 is a cross-shaped mark, which is formed in the center of the alignment mark region R2. The alignment mark region R2 may be a square region with a size of, for example, about 120 μm*120 μm. However, the disclosure is not limited thereto. Various shapes of the alignment mark pattern 124 could be applied, such as a modification of a cross shape, a triangular, a circular shape, an irregular shape, or any other suitable shapes. It is possible to use any shape of the alignment mark pattern 124 for the alignment of the semiconductor device 100.

Referring back to FIG. 1, in some embodiments, a passivation layer 160 is formed over the upper layer 120 and having at least one opening OP1 exposing at least a portion of the upper electrical pattern 122. In the present embodiment, the passivation layer 160 is made of transparent material and covers the alignment mark pattern 124. However, in other embodiment, the passivation layer 160 may be non-transparent, i.e., opaque, and having an opening exposing the alignment mark region R2 for alignment process performed subsequently. The passivation layer 160 may include silicon oxide, silicon nitride, or any suitable dielectric material. In some embodiments, at least one electrical connector 150 is formed over the passivation layer 160 and bonded to the upper electrical pattern 122 through the opening OP1. The electrical connector 150 may include a conductive bump including gold, a multilayer of copper/nickel/gold (Cu/Ni/Au), or the like. In some embodiment, a UBM (Under Bump Metal) film may be formed in the opening OP1 and interposed between the upper electrical pattern 122 and the electrical connector 150.

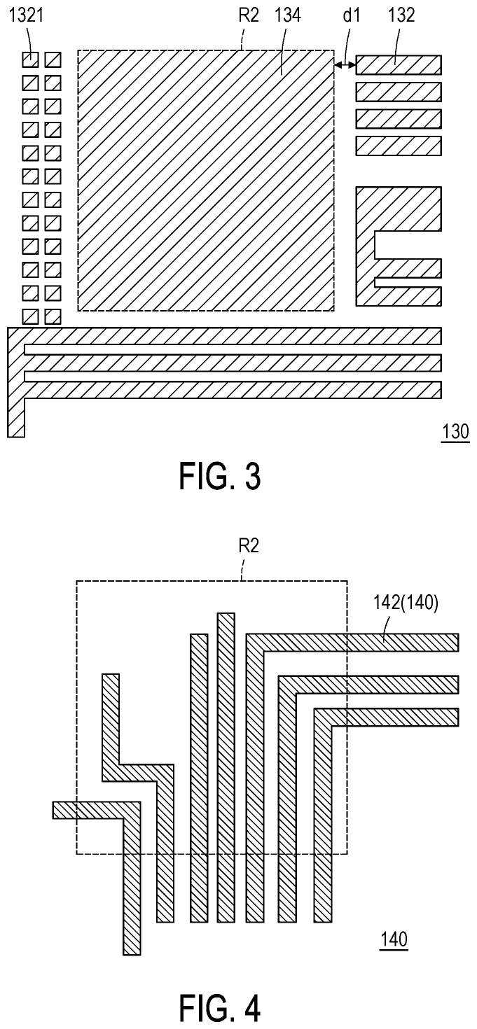

FIG. 3 is a schematic top view of a lower layer of a semiconductor device according to some exemplary embodiments in the present disclosure. Referring to FIG. 1 and FIG. 3, the lower layer 130 is disposed between the substrate 110 and the upper layer 120 and includes a lower electrical pattern 132, in the integrated circuit region R1 (e.g., the integrated circuit region R1 shown in FIG. 1 and FIG. 2), and a dummy pattern 134, in the alignment mark region R2, electrically insulated from the lower electrical pattern 132. In some embodiments, the lower electrical pattern 132 is spaced apart from the dummy pattern 134 by a gap d1. In the present embodiment, the gap d1 may be substantially equal to or greater than 5 μm. In some embodiments, the dummy pattern 134 in the alignment mark region R2 may be a dummy pad, which is a solid pattern as shown in FIG. 2. In the present embodiment, the lower layer 130 is a topmost metallization layer of the redistribution structure underneath the upper layer 120, i.e., the bonding pad layer. In some embodiments, the lower layer 130 may further include a plurality of dummy grids 1321, which are electrically insulated from the lower electrical pattern 132 and the alignment mark pattern 134, for reducing issue of stress concentration. In the present embodiment, the dummy grids 1321 may be aligned with the dummy grids 1221, but in other embodiments, the dummy grids 1321 may not be aligned with the dummy grids 1221.

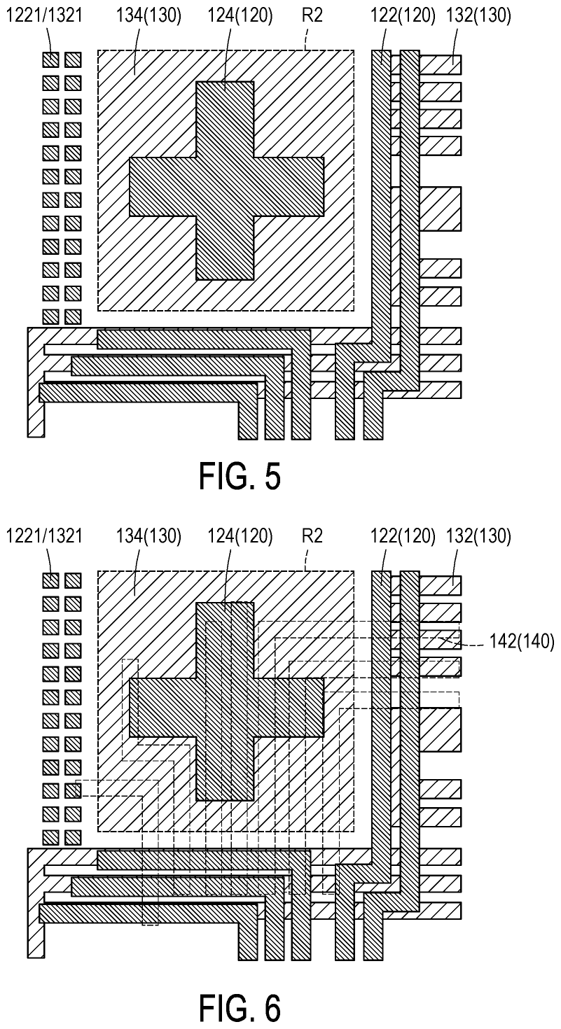

FIG. 5 is a schematic top view of an upper layer and a lower layer of a semiconductor device according to some exemplary embodiments in the present disclosure. Referring to FIG. 1 and FIG. 5, in some embodiments, the alignment mark pattern 124 of the upper layer 120 overlaps the dummy pattern 134 of the lower layer 130 from a top view shown in FIG. 5. In the present embodiment, the dummy pattern 134 completely fills the alignment mark region R2 (including the clearance area surrounding the alignment mark pattern 124) from a top view. In some embodiments, the alignment mark pattern 124 is electrically insulated from the dummy pattern 134 without any vias connected in between, while the upper electrical pattern 122 is electrically connected to the lower electrical pattern 132 through vias 123, as shown in FIG. 1.

In the present embodiment, from a top view, the dummy pattern 134 filling the alignment mark region R2 is a square pattern, and the alignment mark pattern 124 is a cross-shaped mark located at the center of the dummy pattern 134. The material of the dummy pattern 134 is different from the material of the alignment mark pattern 124. To be more specific, the material of the dummy pattern 134 and the material of the alignment mark pattern 124 are selected in pair such that the alignment mark pattern 124 has an optical contrast in relation to the dummy pattern 134, and the optical contrast is substantially equal to or greater than 50. Accordingly, when the alignment mark region R2 is irradiated with light for alignment, the reflectivity of the light reflected from the dummy pattern 134 is different from that of the light reflected from the alignment mark pattern 124. Since the reflectivity of the light reflected from the dummy pattern 134 is different from that of the alignment mark pattern 124, the optical contrast between the dummy pattern 134 and the alignment mark pattern 124 is generated and therefore the alignment mark pattern 124 could be recognized by a camera. In some embodiments, the reflectivity of the material of the alignment mark pattern 124 is chose to be lower than that of the dummy pattern 134, and therefore, the darker alignment mark pattern 124 emerges over the brighter dummy pattern 134 and thus the alignment mark pattern 124 could be recognized.

By definition, the optical contrast could be referred to as a difference between a grey scale value of the dummy pattern 134 and a grey scale value of the alignment mark pattern 124, which may be obtained by analysing the image captured by the camera. In other words, the difference of the grey scale value indicating the optical contrast between the alignment mark pattern 124 and the dummy pattern 134. In some embodiments, the material of the dummy pattern 134 and the material of the alignment mark pattern 124 are selected in pair such that a ratio of the grey scale value of the dummy pattern 134 to the grey scale value of the alignment mark pattern 124 is substantially equal to or greater than 1.3.

For example, the material of the upper layer 120 (including the alignment mark pattern 124) includes aluminium (Al), or aluminium with titanium nitride (TiN), which is an aluminium patterned layer covered with an intermediate conductive layer such as titanium nitride. Accordingly, the material of the lower layer 130 (including the dummy pattern 134) may be selected to be silicon (Si). In other embodiment, when the material of the alignment mark pattern 124) includes aluminium with titanium nitride (TiN), the material of the dummy pattern 134 may be selected to be copper, or the like. The material of the dummy pattern 134 and the material of the alignment mark pattern 124 are selected in pair such that the difference between the grey scale value of the dummy pattern 134 and the grey scale value of the alignment mark pattern 124 could be recognized by the camera for alignment.

FIG. 4 is a schematic top view of an interconnect structure of a semiconductor device according to some exemplary embodiments in the present disclosure. FIG. 6 is a schematic top view of a semiconductor device according to some exemplary embodiments in the present disclosure. Referring to FIG. 1, FIG. 4 and FIG. 6, in some embodiments, the semiconductor device 100 further includes an interconnect structure 140 disposed between the lower layer 130 and the substrate 110. As shown in FIG. 1, the interconnect structure 140 is electrically connected to the lower electrical pattern 132 through at least one via 144 and is electrically insulated from the dummy pattern 134, i.e., no via is connected between the interconnect structure 140 and the dummy pattern 134.

In some embodiments, the interconnect structure 140 includes a plurality of interconnect circuit 142 and a plurality of vias 144 in one or more IMD (inter-metal dielectric) layers. In some embodiments, the interconnect structure 140 may be a BEOL (back end of line) interconnect structure above the device layer (including transistors). Owing to the configuration of the dummy pattern 134 interposed between the alignment mark pattern 124 and the interconnect structure 140, a part of the interconnect circuit 142 of the interconnect structure 140 could extended to the region right underneath the alignment mark 124 and the dummy pattern 134 without interfering the recognition of the alignment mark 124 by the camera. That is, from a top view shown in FIG. 6, a part of the interconnect circuit 142 of the interconnect structure 140 could overlap the dummy pattern 134 and the alignment mark region R2 including the clearance area surrounding the alignment mark 124. Accordingly, routing of the interconnect circuit 142 of the interconnect structure 140 does not need to avoid the region right underneath the alignment mark region R2 since the dummy pattern 134 blocks the interconnect circuit 142 underneath and provides sufficient optical contrast for the camera to recognize the alignment mark 124. Thereby, space usage efficiency of the semiconductor device 100 and flexibility in designing circuit routing are significantly increased.

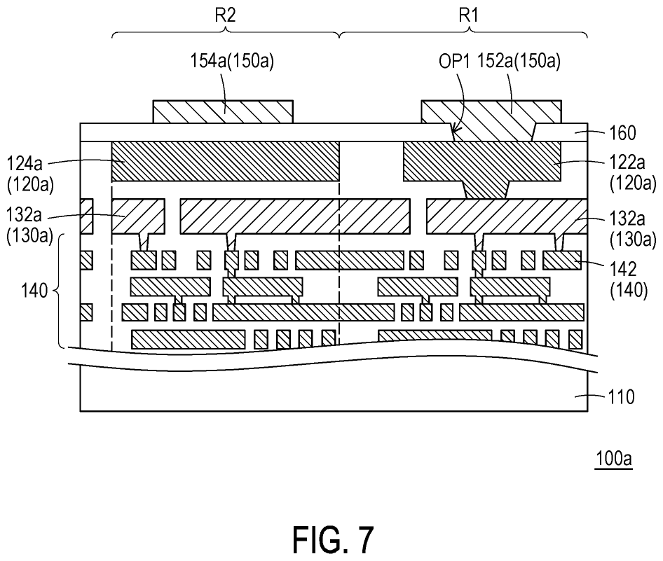

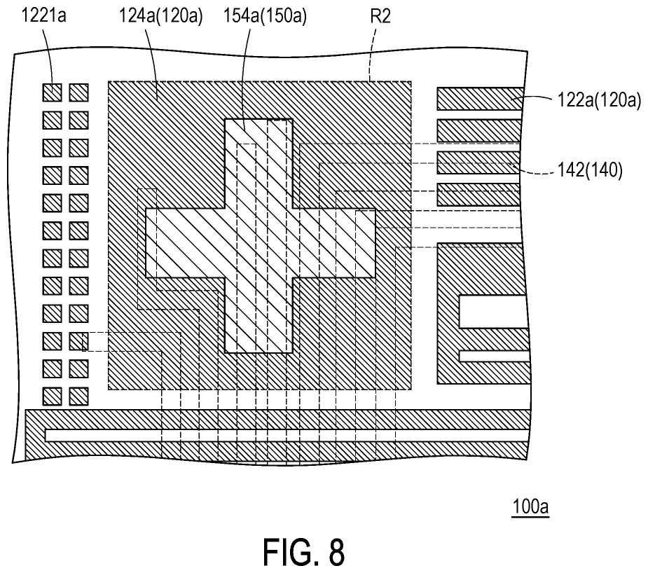

FIG. 7 is a schematic cross-sectional view of a semiconductor device according to another exemplary embodiment in the present disclosure. FIG. 8 is a schematic top view of a semiconductor device according to another exemplary embodiments in the present disclosure. It is noted that the semiconductor device 100a shown in FIG. 7 and FIG. 8 contains many features same as or similar to the semiconductor device disclosed in the previous embodiments. For purpose of clarity and simplicity, detail description of same or similar features may be omitted, and the same or similar reference numbers denote the same or like components.

Referring to FIG. 7 and FIG. 8, in the present embodiment, the upper layer 150a including the alignment mark pattern 154a is the layer of the electrical connector. That is, the upper layer 150a includes an upper electrical pattern 152a, which includes electrical connectors, and an alignment mark pattern 154a electrically insulated from the upper electrical pattern 152a. In other words, the alignment mark pattern 154a of the present embodiment is formed with the upper electrical pattern (electrical connectors) 152a in the same layer (level) simultaneously by one pattering process, such as photolithography process, or the like. As such, the material of the upper layer 150a may include a conductive bump made of gold, a multilayer of copper/nickel/gold (Cu/Ni/Au), or the like. In other embodiment, the material of the alignment mark pattern 154a may include silicon (Si), or the like.

In detail, the upper layer 150a includes an integrated circuit region R1 (e.g., the integrated circuit region R1 shown in FIG. 1 and FIG. 2) in which an array of electrical connectors 152a (one of the electrical connectors 152a is illustrated, but not limited thereto) are formed, and an alignment mark region R2 in which the alignment mark pattern 154a is formed for aligning and positioning, for example, during mounting the semiconductor device 100a on a mounting substrate, or the like. In the present embodiment, the alignment mark pattern 154a is formed in the same layer of the electrical connectors 152a over the interconnect structure.

In some embodiments, the upper layer 150a includes a clearance area, which is a portion in the alignment mark region R2 that surrounds the alignment mark pattern 154a, and the upper electrical pattern 152a, which is the electrical connector, is disposed outside the clearance area, so as to ensure contrast difference between the alignment mark pattern 154a and the background without interference of the upper electrical pattern 152a. In some embodiments, the passivation layer 160 is formed underneath the upper layer 150a and having at least one opening OP1 exposing at least a portion of the bonding pads 122a, which is referred to as the lower electrical pattern in the present embodiment. In the present embodiment, the passivation layer 160 completely covers the dummy pattern 124a underneath the alignment mark pattern 154a, so that the passivation layer 160 is interposed between the alignment mark pattern 154a and the dummy pattern 124a for electrical insulation. In the present embodiment, the alignment mark pattern 154a is a cross-shaped mark, which is formed in the center of the alignment mark region R2. The alignment mark region R2 may be a square region with a size of, for example, about 120 μm*120 μm. However, the disclosure is not limited thereto. Various shapes of the alignment mark pattern 154a could be applied, such as a modification of a cross shape, a triangular, a circular shape, an irregular shape, or any other suitable shapes. It is possible to use any shape of the alignment mark pattern 154a for the alignment of the semiconductor device 100a.

In some embodiments, the lower layer 120a including the dummy pattern 124a is the layer of the bonding pads. That is, the lower layer 120a includes a lower electrical pattern 122a, which includes an array of bonding pads, and a dummy pattern 124a electrically insulated from the lower electrical pattern 122a. In other words, the dummy pattern 124a of the present embodiment is formed with the lower electrical pattern (bonding pads) 122a in the same layer (level) simultaneously by one pattering process, such as photolithography process, or the like.

The lower layer 120a is disposed between the substrate 110 and the upper layer 150a. In some embodiments, the lower electrical pattern 122a is spaced apart from the dummy pattern 124a by a gap. In some embodiments, the dummy pattern 124a may be a dummy pad, which is a solid pattern as shown in FIG. 8. In some embodiments, the lower layer 120a may further include a plurality of dummy grids 1221a, which are electrically insulated from the lower electrical pattern 122a and the dummy pattern 124a, for reducing issue of stress concentration.

In some embodiments, the alignment mark pattern 154a of the upper layer 150a overlaps the dummy pattern 124a from a top view shown in FIG. 8. In the present embodiment, the dummy pattern 124a completely fills the alignment mark region R2 (including the clearance area surrounding the alignment mark pattern 154a) from a top view. In some embodiments, the alignment mark pattern 154a is electrically insulated from the dummy pattern 124a without any vias connected in between, while the upper electrical pattern (electrical connector) 152a is electrically connected to the lower electrical pattern (bonding pad) 122a as shown in FIG. 7.

In the present embodiment, the material of the dummy pattern 124a is different from the material of the alignment mark pattern 154a. To be more specific, the material of the dummy pattern 124a and the material of the alignment mark pattern 154a are selected in pair such that the alignment mark pattern 154a has an optical contrast in relation to the dummy pattern 124a, and the optical contrast is substantially equal to or greater than 50. That is, the difference between a grey scale value of the alignment mark pattern 154a and a grey scale value of the dummy pattern 124a is substantially equal to or greater than 50. Accordingly, when the alignment mark region R2 is irradiated with light for alignment, the reflectivity of the light reflected from the dummy pattern 124a is different from that of the light reflected from the alignment mark pattern 154a. Since the reflectivity of the light reflected from the dummy pattern 124a is different from that of the alignment mark pattern 154a, there is generated the optical contrast between the dummy pattern 124a and the alignment mark pattern 154a and therefore the alignment mark pattern 154a could be recognized by a camera. In some embodiments, the reflectivity of the material of the alignment mark pattern 154a is chose to be lower than that of the dummy pattern 124a, and therefore, the darker alignment mark pattern 154a emerges over the brighter dummy pattern 124a and thus the alignment mark pattern 154a could be recognized. In some embodiments, the material of the dummy pattern 124a and the material of the alignment mark pattern 154a are selected in pair such that a ratio of the grey scale value of the dummy pattern 124a to the grey scale value of the alignment mark pattern 154a is substantially equal to or greater than 1.3.

For example, the material of the upper layer 150a (including the alignment mark pattern 154a and electrical connector 152a) includes gold, a multilayer of copper/nickel/gold (Cu/Ni/Au), or the like. Accordingly, the material of the lower layer 120a (including the dummy pattern 124a and the bonding pad 122a) may be selected to be aluminium (Al), or the like.

Accordingly, the semiconductor device 100a includes an interconnect structure 130a, 140 disposed between the lower layer 120a and the substrate 110. As shown in FIG. 7, the interconnect structure 130a is electrically connected to the lower electrical pattern 122a through at least one via and is electrically insulated from the dummy pattern 124a, i.e., no via is connected between the interconnect structure 130a and the dummy pattern 124a.

In some embodiments, the interconnect structure 130a, 140 includes a plurality of interconnect circuit 132a, 142 and a plurality of vias in one or more IMD layers. Owing to the configuration of the dummy pattern 124a interposed between the alignment mark pattern 154a and the interconnect structure 130a, 140, a part of the interconnect circuit 132a, 142 of the interconnect structure 130a, 140 could extended to the region right underneath the alignment mark 154a and the dummy pattern 124a without interfering the recognition of the alignment mark 154a by the camera. That is, from a top view shown in FIG. 8, a part of the interconnect circuit 132a, 142 of the interconnect structure 130a, 140 could overlap the dummy pattern 124a and the alignment mark region R2 including the clearance area surrounding the alignment mark 154a.

Based on the above discussions, it could be seen that the present disclosure offers various advantages. It is understood, however, that not all advantages are necessarily discussed herein, and other embodiments may offer different advantages, and that no particular advantage is required for all embodiments.

In sum, the semiconductor device of the disclosure is configured with a dummy pattern of a lower layer underneath the alignment mark pattern of the upper layer. As such, the material of the dummy pattern and the material of the alignment mark pattern are selected in pair such that the alignment mark pattern has an optical contrast in relation to the dummy pattern, and the optical contrast is substantially equal to or greater than 50 and therefore the alignment mark pattern 124 could be well recognized by a camera.

Owing to the configuration of the dummy pattern interposed between the alignment mark pattern and the interconnect structure, a part of the interconnect circuit of the interconnect structure could overlap the dummy pattern from a top view since the dummy pattern blocks the interconnect circuit underneath and provides sufficient optical contrast for the camera to recognize the alignment mark. Thereby, space usage efficiency of the semiconductor device and flexibility in designing circuit routing are significantly increased.

It will be apparent to those skilled in the art that various modifications and variations could be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A semiconductor device, comprising:
a substrate;
an upper layer disposed over the substrate and comprises an upper electrical pattern and an alignment mark pattern electrically insulated from the upper electrical pattern; and
a lower layer disposed between the substrate and the upper layer and comprising a lower electrical pattern and a dummy pattern electrically insulated from the lower electrical pattern, wherein the alignment mark pattern overlaps the dummy pattern from a top view, the alignment mark pattern has an optical contrast in relation to the dummy pattern, and the optical contrast is substantially equal to or greater than 50.

2. The semiconductor device as claimed in claim 1, wherein the upper layer comprises a clearance area surrounding the alignment mark pattern, and the upper electrical pattern is disposed outside the clearance area.

3. The semiconductor device as claimed in claim 2, wherein the dummy pattern completely filling the clearance area from a top view.

4. The semiconductor device as claimed in claim 2, wherein the upper electrical pattern is spaced apart from the clearance area by a gap, which is substantially equal to or greater than 5 μm.

5. The semiconductor device as claimed in claim 1, further comprising an interconnect structure disposed between the lower layer and the substrate, and a part of the interconnect circuit of the interconnect structure overlaps the dummy pattern from a top view.

6. The semiconductor device as claimed in claim 5, wherein the interconnect structure is electrically connected to the lower electrical pattern and electrically insulated from the dummy pattern.

7. The semiconductor device as claimed in claim 1, wherein the upper electrical pattern comprises a bonding pad for bonding with an electrical connector and material of the upper layer comprises aluminium, or aluminium with titanium nitride.

8. The semiconductor device as claimed in claim 7, wherein the material of the lower layer comprises copper.

9. The semiconductor device as claimed in claim 1, wherein the upper electrical pattern comprises an electrical connector, and material of the upper layer comprises gold, or a multilayer of Cu/Ni/Au.

10. The semiconductor device as claimed in claim 9, wherein the material of the lower layer comprises aluminium.

11. The semiconductor device as claimed in claim 1, wherein the alignment mark pattern is electrically insulated from the dummy pattern.

12. The semiconductor device as claimed in claim 1, wherein the optical contrast is a difference between a grey scale value of the dummy pattern and a grey scale value of the alignment mark pattern.

13. The semiconductor device as claimed in claim 1, wherein a ratio of a grey scale value of the dummy pattern to a grey scale value of the alignment mark pattern is substantially equal to or greater than 1.3.

14. A semiconductor device, comprising:
a substrate;
an upper layer disposed over the substrate and comprising an upper electrical pattern and an alignment mark pattern electrically insulated from the upper electrical pattern;
a lower layer disposed between the substrate and the upper layer and comprising a lower electrical pattern and a dummy pad electrically insulated from the lower electrical pattern, wherein the alignment mark pattern overlaps the dummy pad from a top view; and
an interconnect structure disposed between the lower layer and the substrate, wherein a part of the interconnect circuit of the interconnect structure overlaps the dummy pattern from a top view.

15. The semiconductor device as claimed in claim 14, wherein the alignment mark pattern has an optical contrast in relation to the dummy pad, and the optical contrast is substantially equal to or greater than 50.

16. The semiconductor device as claimed in claim 14, wherein the upper layer comprises a clearance area surrounding the alignment mark pattern, and the upper electrical pattern is disposed outside the clearance area.

17. The semiconductor device as claimed in claim 16, wherein the dummy pattern completely filling the clearance area from a top view.

18. The semiconductor device as claimed in claim 16, wherein the part of the interconnect circuit pattern overlaps the clearance area from a top view.

19. The semiconductor device as claimed in claim 14, wherein the interconnect structure is electrically connected to the lower electrical pattern and electrically insulated from the dummy pattern.

20. The semiconductor device as claimed in claim 14, wherein the upper electrical pattern comprises a bonding pads for bonding with an electrical connector, and material of the upper layer comprises aluminium, or aluminium titanium nitride.

21. The semiconductor device as claimed in claim 20, wherein the material of the lower layer comprises copper.

22. The semiconductor device as claimed in claim 14, wherein the upper electrical pattern comprises an electrical connector, and material of the upper layer comprises gold, or a multilayer of Cu/Ni/Au.

23. The semiconductor device as claimed in claim 22, wherein the material of the lower layer comprises aluminium.
